(19) United States
(12) Patent Application Publication
(10) Pub. No.: US 2022/0248541 A1
(43) Pub. Date: Aug. 4, 2022

(54) SYSTEM IN PACKAGE (SIP) SOCKET CONNECTOR INTERFACE

(71) Applicant: QUALCOMM Incorporated, San Diego, CA (US)

(72) Inventors: Daniel Daeik KIM, San Diego, CA (US); Changhan Hobie YUN, San Diego, CA (US); Paragkumar Ajaybhai THADESAR, San Diego, CA (US); Nosun PARK, Incheon (KR); Sameer Sunil VADHAVKAR, San Diego, CA (US)

(21) Appl. No.: 17/164,458

(22) Filed: Feb. 1, 2021

(51) Int. Cl. H05K 5/00; H01R 12/72; H01R 43/20

(52) U.S. Cl. CPC H05K 5/006; H01R 43/205; H01R 12/727

(57) ABSTRACT

Certain aspects of the present disclosure generally relate to an electronic device. One example electronic device generally includes a SIP module having a circuit board and one or more electronic elements disposed above the circuit board, and one or more first connector contacts coupled to a bottom surface of the circuit board, the one or more first connector contacts being configured to electrically couple the circuit board to a connector receptacle.

### BACKGROUND

### Field of the Disclosure

Certain aspects of the present disclosure generally relate to an electronic device and, more particularly, to a connector interface for a system in package (SIP) module.

### Description of Related Art

A continued emphasis in electronic components and semiconductor technology is to create improved performance devices at competitive prices and with smaller sizes. This emphasis over the years has resulted in miniaturization of electronic devices, made possible by continued advances in processes and materials in combination with new and sophisticated device designs. For example, this desire for miniaturization has led to smaller package designs for electronic components, such as using a system in package (SIP) design for electronic components.

A SIP module generally refers to a packaged assembly of multiple integrated circuits (ICs). A SIP module may perform all or many of the functions of an electronic system, and may be implemented in mobile devices, such as phones or music players. The SIP module may be coupled to one or more other circuits through a connector or cable.

### SUMMARY

The systems, methods, and devices of the disclosure each have several aspects, no single one of which is solely responsible for its desirable attributes. Without limiting the scope of this disclosure as expressed by the claims which follow, some features will now be discussed briefly. After considering this discussion, and particularly after reading the section entitled “Detailed Description” one will understand how the features of this disclosure provide advantages that include reduced area consumption of an electronic device having a system in package (SIP) module configured for coupling to a connector.

Certain aspects of the present disclosure provide an electronic device. The electronic device generally includes a SIP module having a circuit board and one or more electronic elements disposed above the circuit board, and one or more first connector contacts coupled to a bottom surface of the circuit board, the one or more first connector contacts being configured to electrically couple the circuit board to a connector receptacle.

Certain aspects of the present disclosure provide a connector receptacle. The connector receptacle generally includes a first supporting element, a second supporting element, the first supporting element and the second supporting element being configured to support a portion of a SIP module to be disposed between the first supporting element and the second supporting element, and one or more first connector contacts on the first supporting element, the one or more first connector contacts being configured to electrically couple a circuit to one or more second connector contacts coupled to a circuit board of the SIP module.

Other aspects of the present disclosure generally relate to a method for fabricating an electronic device. An exemplary fabrication method generally includes forming a SIP module, wherein forming the SIP module includes forming a circuit board and forming one or more electronic elements above the circuit board. The method further includes forming one or more first connector contacts such that the one or more first connector contacts are coupled to a bottom surface of the circuit board, the one or more first connector contacts being configured to electrically couple the circuit board to a connector receptacle.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be by reference to aspects, some of which are illustrated in the appended drawings. It is to be noted, however, that the appended drawings illustrate only certain aspects of this disclosure and are therefore not to be considered limiting of its scope, for the description may admit to other equally effective aspects.

FIG. 1 is a schematic diagram of an example electronic device having a system in package (SIP) module coupled to a connector, viewed as a cross-section through the SIP module and connector, in accordance with certain aspects of the present disclosure.

FIGS. 2A and 2B are cross-sectional views of a connector and a SIP module coupled to the connector, respectively, in accordance with certain aspects of the present disclosure.

FIGS. 3A and 3B are cross-sectional views of a portion of an example electronic device in unassembled and assembled configurations, respectively, according to certain aspects of the present disclosure.

FIGS. 4A and 4B are cross-sectional views of a portion of an example electronic device having a connector encircling an edge of a circuit board in unassembled and assembled configurations, respectively, according to certain aspects of the present disclosure.

FIGS. 5A and 5B are cross-sectional views of a portion of an example electronic device having a cable traversing along a bottom surface of a SIP module in unassembled and assembled configurations, respectively, according to certain aspects of the present disclosure.

FIGS. 6A and 6B are cross-sectional views of a portion of an example electronic device having a cable traversing a top surface of a SIP module in unassembled and assembled configurations, according to certain aspects of the present disclosure.

FIG. 7 is a cross-sectional view of a portion of an electronic device including a SIP module having connector contacts coupled to top, bottom, and lateral surfaces of the SIP module, in accordance with certain aspects of the present disclosure.

FIGS. 8A and 8B are cross-sectional views of the portion of the electronic device of FIG. 7 in unassembled and assembled configurations, respectively, according to certain aspects of the present disclosure.

FIG. 9 is a cross-sectional view of the SIP module of FIG. 1, in which certain aspects of the present disclosure may be practiced.

FIG. 10 is a flow diagram of example operations for fabricating an electronic device, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure relate to an electronic device having a system in package (SIP) module (e.g., a radio frequency (RF) module) and one or more contacts on a surface (e.g., a bottom surface) of a circuit board of the SIP module. One example electronic device generally includes a SIP module having a circuit board and one or more electronic elements disposed above the circuit board, and one or more first connector contacts coupled to a bottom surface of the circuit board and configured to electrically couple the circuit board to a connector receptacle. Furthermore, certain aspects are directed toward such a connector receptacle. An example connector receptacle may include a first supporting element and a second supporting element. The first supporting element and the second supporting element may be configured to support a portion of a SIP module to be disposed between the first supporting element and the second supporting element. The first supporting element may include one or more first connector contacts configured to electrically couple a circuit to one or more second connector contacts coupled to a circuit board of the SIP module.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

Traditionally, a SIP module may be placed on a circuit board, and additional assembly structures may be implemented on the circuit board that allow for coupling between the SIP module and a connector receptacle. That is, a connector receptacle (or plug) electrically connected to the contacts of the SIP module may be mounted on top of or next to the SIP module itself, and a separate connector plug (or receptacle) with a cable (e.g., a ribbon cable) may be mated to this connector receptacle (or plug). In this configuration, the space used by this connector assembly may be relatively large, resulting in high connector and surface mount technology (SMT) costs due to the increased space used for electrical and physical connection(s). Moreover, a designer's freedom of placement of components may be negatively impacted by this configuration.

Accordingly, certain aspects provide contacts on a surface (e.g., bottom surface) of a SIP module such that the SIP module itself can be plugged into a connector (receptacle). For example, as described further herein, a connector may be designed to fit the shape of the SIP module (e.g., an end portion of the SIP module). The connector may be physically attached to an edge of the SIP module, encircling that edge. Contacts of the connector may be electrically coupled to contacts on the bottom surface (and/or other surfaces) of the SIP module. Thus, the total space for the connection between the connector and the SIP module may be reduced. By reducing the total space for the connection between the SIP module and the connector, space for other surface mount components can be made available, the size of the electronic device can be diminished, and/or costs can be reduced.

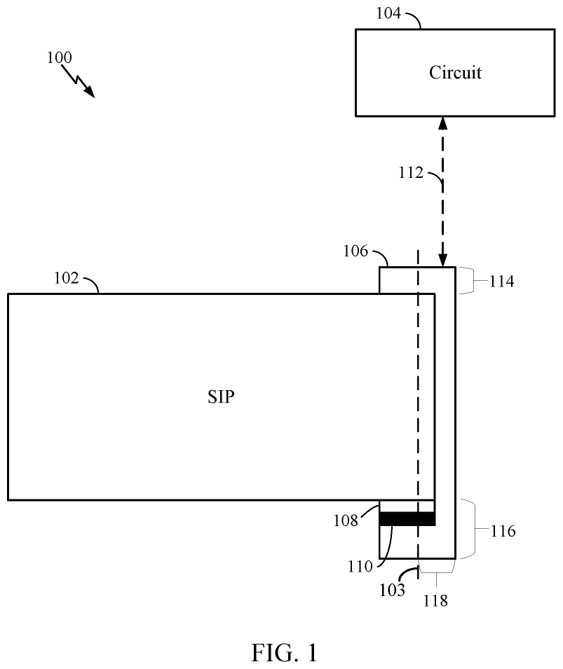

FIG. 1 is a schematic diagram of an example electronic device 100, in accordance with certain aspects of the present disclosure. As illustrated, the electronic device 100 may include a SIP module 102 (e.g., a RF module or any other suitable SIP module), a circuit 104, and a connector 106 (also referred to as a “connector receptacle”). FIG. 1 is a cross-sectional view through the connector 106. The SIP module 102 may be plugged into the connector 106 such that the SIP module 102 is physically coupled to the connector 106, as shown. The connector 106 may facilitate electrical coupling between the SIP module 102 and circuit 104 via a connection element such as a ribbon cable, as represented by the dashed arrow 112 between the connector 106 and circuit 104. In certain aspects, the electronic device 100 may be a smartphone or any of other various suitable portable electronic devices. In some cases, the circuit 104 may be another circuit on the electronic device such as an integrated circuit (IC), which may be a digital-to-analog converter (DAC), an analog-to-digital converter (ADC), a digital signal processor (DSP), a controller, etc.

Electrical coupling between the SIP module 102 and the connector 106 may be facilitated using one or more contacts 108 coupled to a bottom surface (and/or other surfaces, not shown in FIG. 1) of the SIP module 102 and one or more contacts 110 of the connector 106. For example, the contacts 108 and contacts 110 are electrically conductive contacts and may be composed of copper (Cu) or any other suitable electrically conductive material. When the SIP module 102 is plugged into the connector 106, the one or more contacts 108 may be electrically coupled to the one or more contacts 110 of the connector 106, electrically coupling the SIP module and circuit 104. In other words, the contacts 110 of the connector 106 may correspond to (e.g., align with) the contacts 108 of the SIP module 102.

In some aspects, the connector 106 may be shaped such that a physical connection to the SIP module 102 can be made. For instance, the connector 106 may be configured to encircle an edge (e.g., an end portion) of the SIP module 102, as shown. In other words, an edge of the SIP module 102 may be disposed between a top supporting element 114 (which may also be referred to herein as a “connector wall”) of the connector 106 and a bottom supporting element 116 (which may also be referred to herein as a “connector wall”) of the connector 106. In certain aspects, the connector 106 may also include one or more lateral supporting elements (e.g., supporting element 118) connected between the top supporting element 114 and the bottom supporting element 116.

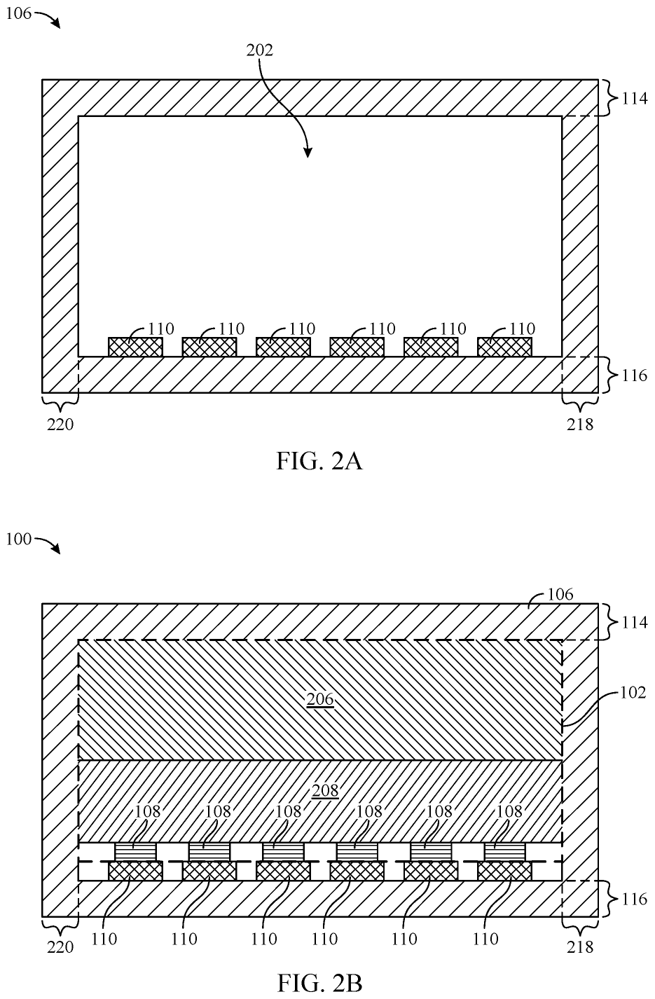

FIG. 2A is a cross-sectional view of the connector 106, and FIG. 2B is a cross-sectional view of the SIP module 102 coupled to the connector 106, both through line segment 103 shown in FIG. 1, in accordance with certain aspects of the present disclosure. As shown in FIG. 2A, the connector 106 may have four supporting elements 114, 116, 218, 220 (e.g., also referred to herein as “connector walls”) arranged such that a region 202 between the supporting elements is configured to receive an end portion (or edge) of a corresponding device with which the connector 106 is to be coupled (e.g., electrically and physically coupled). In some cases, the supporting elements 218, 220 may correspond to the one or more supporting elements 118 of FIG. 1. As shown in FIG. 2B, the connector 106 may receive an edge the SIP module 102 and encircle the edges of the end portion of the SIP module 102 for physical coupling. The four supporting elements 114, 116, 218, 220 of the connector 106 may be arranged in the shape of a rectangle (or any suitable shape) such that a space between the four supporting elements corresponds to the shape of the end portion of the SIP module 102. In certain aspects, the four supporting elements 114, 116, 218, 220 may be composed of a polymer (e.g., plastic), a resin, or any suitable material that can provide structural support for the connector 106. Although four supporting elements are shown, it should be appreciated that the connector 106 may be implemented with only three supporting elements, or more than four supporting elements. In other words, the supporting elements may be used to form the region 202 to have the shape of any suitable polygon.

In certain aspects, the bottom supporting element 116 may include the contacts 110 and traverse a bottom surface of (the end portion of) the SIP module 102, as illustrated. Furthermore, the top supporting element 114 may traverse a top surface of (the end portion of) the SIP module 102. As shown, lateral supporting elements 218, 220 may each be adjacent to lateral surfaces of the SIP module 102 and have lengths such that (the end portion of) the SIP module 102 and contacts 108 (when connected to contacts 110) fit within the connector 106.

As shown in FIG. 2B, the SIP module 102 may include molding 206 or another encapsulant material disposed above a circuit board 208 (e.g., a laminate substrate). The molding 206 may encase one or more electronic components (e.g., a radio frequency integrated circuit (RFIC) die and/or any of various other suitable integrated circuit dies or components) that are disposed above the circuit board 208 for inclusion in the SIP module 102.

As illustrated, the SIP module 102 may be electrically coupled to the connector 106 via contacts 108 coupled to a bottom surface of the SIP module 102, such that each of the contacts 108 is electrically coupled to one of the contacts 110 of the connector 106. These contact connections may facilitate electrical connections between the circuit board 208 and another circuit (e.g., circuit 104 of FIG. 1) via a cable, for example.

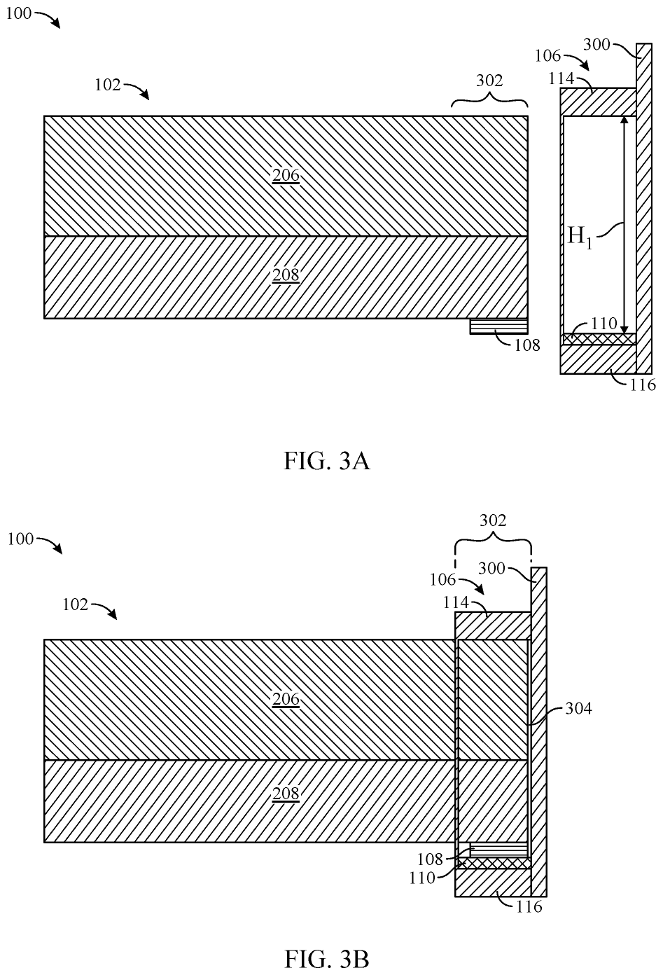

FIGS. 3A and 3B are cross-sectional views of a portion of the electronic device 100 in unassembled and assembled configurations, respectively, according to certain aspects of the present disclosure. As illustrated in FIG. 3A, the supporting elements 114, 116 may be separated by a distance H₁ such that the SIP module 102 and the contacts 108 can fit between the supporting elements 114, 116 and the contacts 110 and such that the connector 106 can encircle an edge 302 (e.g., an end portion) of the SIP module 102, including both the circuit board 208 and the molding 206. As shown, the connector 106 may be coupled to a cable 300 (e.g., a ribbon cable or flexible circuit board functioning as a cable). In certain aspects, cable 300 may provide a means by which (e.g., as shown by the arrow 112 of FIG. 1) the connector 106 is electrically coupled to another circuit (e.g., circuit 104 of FIG. 1). As illustrated in FIG. 3B, the cable 300 may be electrically coupled to the contacts 110 to facilitate electrical coupling between the circuit board 208 and the other circuit (e.g., the circuit 104 of FIG. 1) once the SIP module 102 and the connector 106 are connected together as an assembly.

As shown in FIG. 3B, the connector 106 may be physically attached to the edge 302 of the SIP module 102. Once attached, the contacts 108 of the SIP module 102 may be in electrical connection with the contacts 110 of the connector 106. Furthermore, as shown, the cable 300 may traverse a lateral surface 304 of the SIP module 102 once the SIP module 102 and the connector 106 are assembled together. For example, the cable 300 (or at least a portion of the cable near the connector 106) may be oriented vertically with respect to the SIP module 102 having a longitudinal axis that is oriented horizontally. The supporting elements 114, 116 of the connector may traverse a portion of the top and bottom surfaces, respectively, of the SIP module 102. This may allow for the edge 302 of the SIP module 102 to snugly fit within the supporting elements 114, 116 such that the electrical connection can be maintained and such that the connector 106 does not become dislodged from the SIP module 102 (e.g., during transport and/or while experiencing vibration). Additionally or alternatively, the lateral supporting elements 218, 220 (of FIG. 2B) may traverse lateral portions of the edge 302 of the SIP module 102 such that a reliable electrical and physical connection can be maintained between the SIP module 102 and the connector 106.

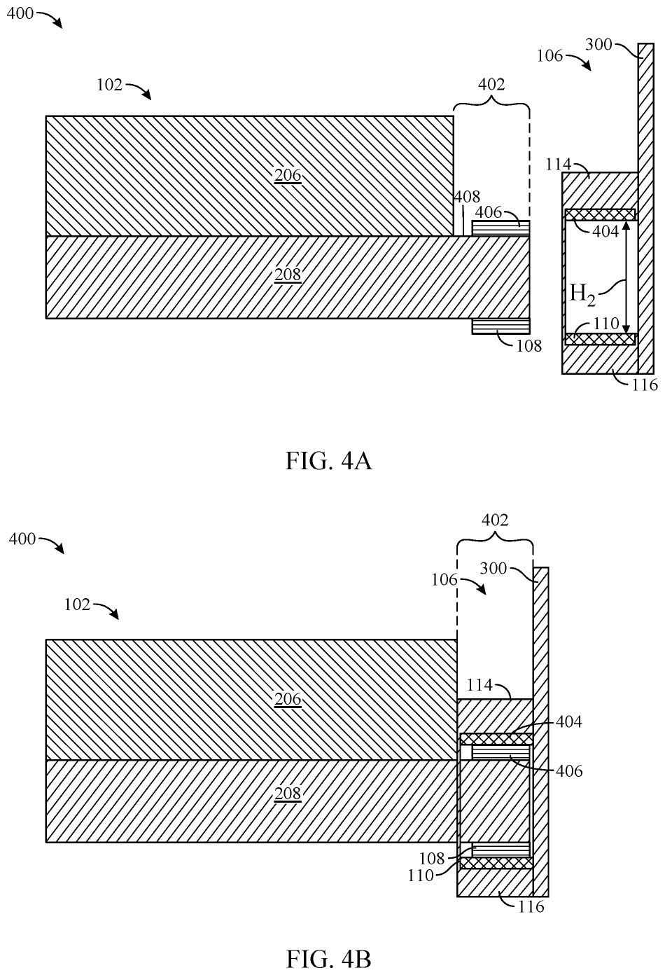

FIGS. 4A and 4B are cross-sectional views of a portion of an example electronic device 400 having the connector 106 encircling an edge 402 (e.g., an end portion) of the circuit board 208, according to certain aspects of the present disclosure. That is, the molding 206 may not cover the edge 402 of the circuit board 208, and the connector 106 may thus not encircle the molding 206. Furthermore, in certain aspects, the connector 106 may further include contacts 404 on the supporting element 114, and contacts 406 may be disposed on a top surface 408 of the circuit board 208. In particular, FIG. 4A illustrates an unassembled configuration of the SIP module 102 and the connector 106, and FIG. 4B illustrates an assembled configuration of the SIP module 102 and the connector 106. The contacts 406 may be electrically coupled to contacts 404 when the electronic device 400 is in the assembled configuration. As shown, the supporting elements 114, 116 may be separated by a distance H₂ (e.g., smaller than distance H₁ described with respect to FIG. 3A) such that the circuit board 208 of the SIP module 102 and the contacts 108, 406 fit between the supporting elements 114, 116 and the contacts 110, 404 once the SIP module 102 and the connector 106 are assembled together. As shown in the assembled configuration of FIG. 4B, the connector 106 may encircle the edge 402 of the circuit board 208 such that the edge 402 of the circuit board 208 and the contacts 108, 406 are between the supporting elements 114, 116. In certain aspects, the supporting element 114 may abut the molding 206 in the assembled configuration, while in other aspects, there may be space between the supporting element 114 and the molding 206 in the assembled configuration.

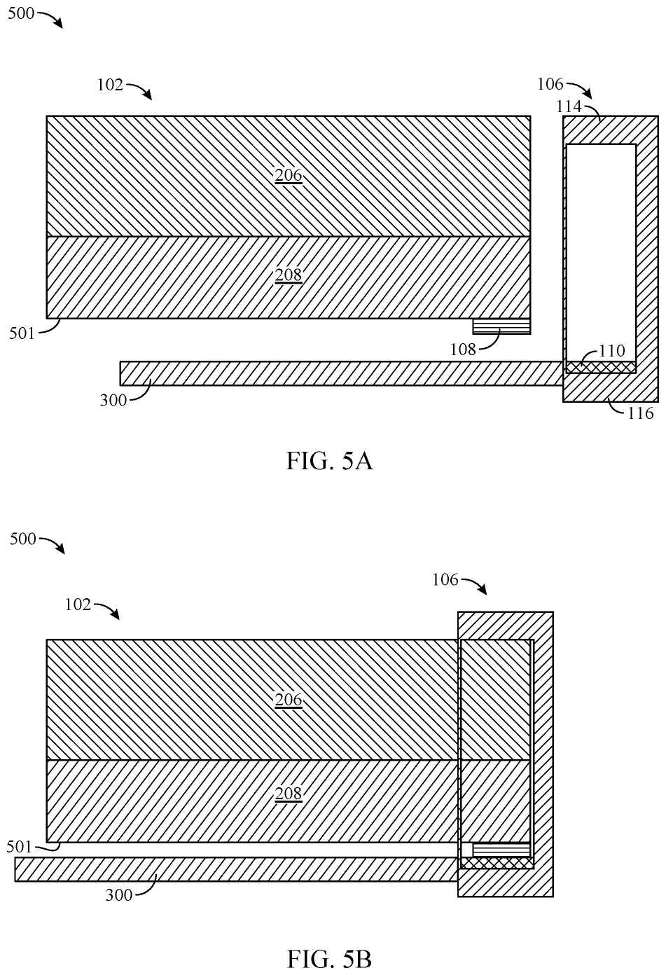

FIGS. 5A and 5B are cross-sectional views of a portion of an example electronic device 500 having the cable 300 traversing along a bottom surface 501 of the SIP module 102, according to certain aspects of the present disclosure. In particular, FIG. 5A illustrates an unassembled configuration of the SIP module 102 and the connector 106, and FIG. 5B illustrates an assembled configuration of the SIP module 102 and the connector 106. As shown, the general structure of the electronic device 500 may be similar to that of the electronic device 100 illustrated in FIGS. 3A and 3B, with the exception that the cable 300 may be configured to traverse the bottom surface 501 of the circuit board 208 of the SIP module 102.

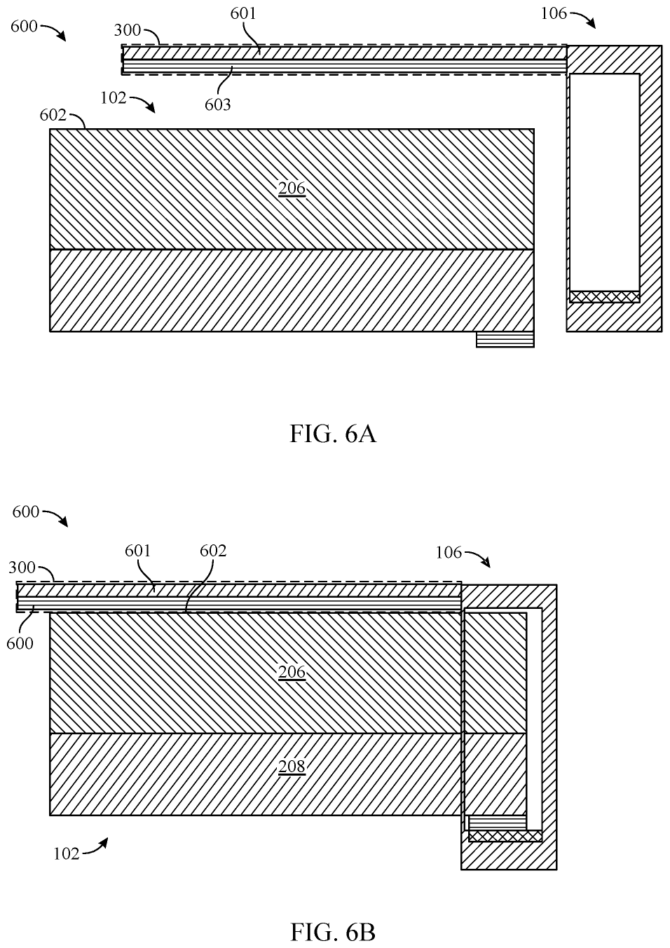

FIGS. 6A and 6B are cross-sectional views of a portion of an example electronic device 600 having the cable 300 traversing a top surface 602 of the SIP module 102, in accordance with certain aspects of the present disclosure. In particular, FIG. 6A illustrates an unassembled configuration of the SIP module 102 and the connector 106, and FIG. 6B illustrates an assembled configuration of the SIP module 102 and the connector 106. The general structure of the electronic device 600 may be similar to that of the electronic device 100 as described with respect to FIGS. 3A and 3B, with the exception that the cable 300 may be configured to traverse the top surface 602 of the SIP module 102. As illustrated, the cable 300 may include conductive material 601 configured to facilitate signaling between the SIP module 102 and another circuit (e.g., circuit 104 described with respect to FIG. 1). In some aspects, the cable 300 may also include a shield (e.g., a shielding sidewall 603) to provide electrical isolation between the conductive material 601 of the cable 300 and the one or more components encased by molding 206.

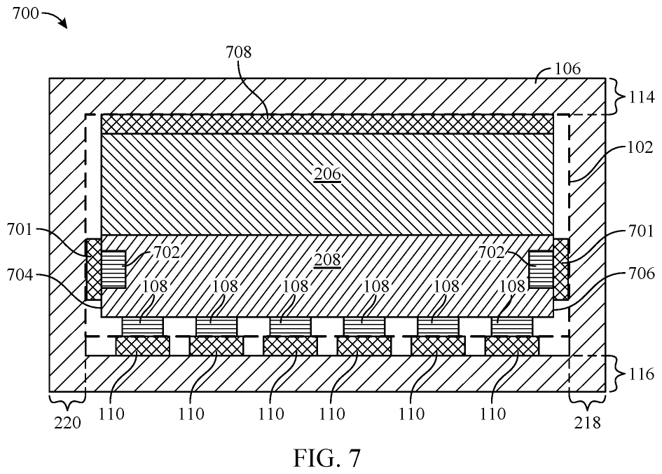

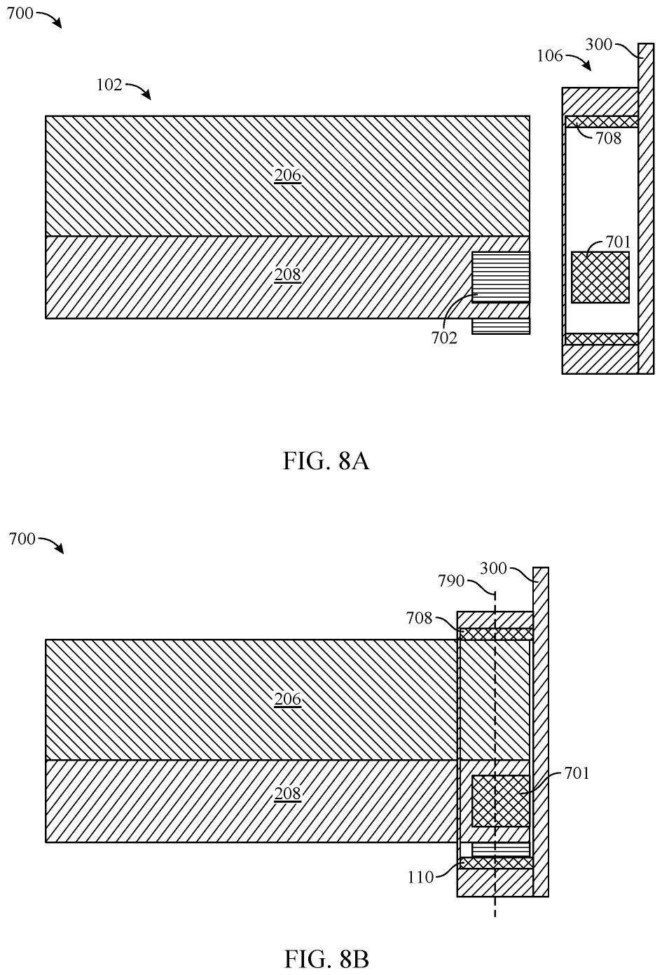

FIG. 7 is a cross-sectional view of a portion of an electronic device 700 including the SIP module 102 having connector contacts coupled to top, bottom, and lateral surfaces of the SIP module 102, in accordance with certain aspects of the present disclosure. Although contacts are shown on the top, bottom, and lateral surfaces of the SIP module 102 in FIG. 7, it should be appreciated that these contacts could be one or more contacts on the top surface, one or more contacts on the bottom surface, and/or one or more contacts on either or both of the lateral surfaces. FIGS. 8A and 8B are cross-sectional views of the portion of the electronic device 700, according to certain aspects of the present disclosure. In particular, FIG. 8A illustrates an unassembled configuration of the SIP module 102 and the connector 106, and FIG. 8B illustrates an assembled configuration of the SIP module 102 and the connector 106. In particular, FIG. 7 illustrates a cross-section of the SIP module 102 and the connector 106 through line segment 790 shown in FIG. 8B.

In FIGS. 7, 8A, and 8B, connector 106 may include one or more side contacts 701 on either or both lateral supporting elements 218, 220. The side contact(s) 701 of the connector 106 may be coupled to one or more side contacts 702 on or at least exposed at either or both corresponding lateral surfaces 704, 706 of the circuit board 208. The lateral surfaces 704, 706 may be surfaces on opposite sides of the circuit board 208. Additionally or alternatively, the connector 106 may include one or more upper contacts 708 adjacent or extending from the top supporting element 114. The upper contact(s) 708 may provide electrical coupling between another circuit (e.g., the circuit 104 described with respect to FIG. 1) and one or more components encased by the molding 206. In some cases, the upper contact(s) 708 may be a shielding layer or may be configured to couple the connector 106 to a shielding layer (not shown) in or above the molding 206. In certain aspects, the side contact(s) 702 may be used for providing power for the SIP module 102 and/or communicating digital signals between the SIP module 102 and the circuit 104. As illustrated in FIG. 8B, once the SIP module 102 and the connector 106 are assembled, the side contact(s) 702 may be electrically coupled to the side contact(s) 701, and the lower contacts 108 may be electrically coupled to the lower contacts 110.

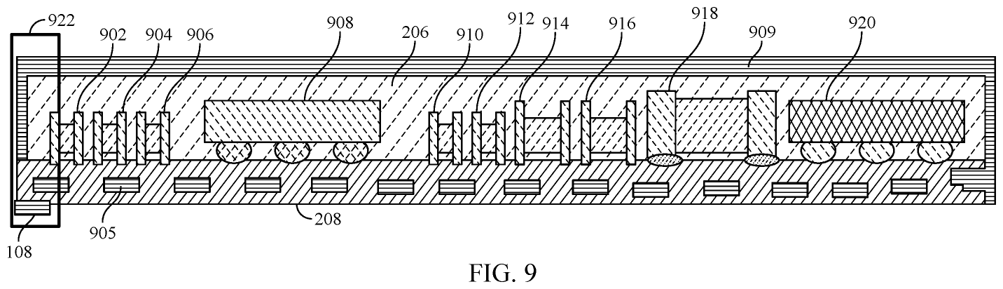

FIG. 9 is a cross-sectional view of the SIP module 102 of FIG. 1, in accordance with certain aspects of the present disclosure. As shown, the SIP module 102 may further include one or more components 902, 904, 906, 908, 910, 912, 914, 916, 918, 920. The one or more components of the SIP module 102 may be encased by the molding 206, which in turn may be encased by a shielding 909 (e.g., an electromagnetic interference (EMI) shielding sputter). In some cases, the shielding 909 may have a thickness between 3 and 5 μm. Furthermore, as illustrated, the circuit board 208 may include one or more traces 905 and/or one or more vias (not shown) to facilitate electrical connection between the one or more components of the SIP module 102. In certain aspects, the SIP module 102 may be configured to be coupled to a connector (e.g., connector 106), as represented by the box 922.

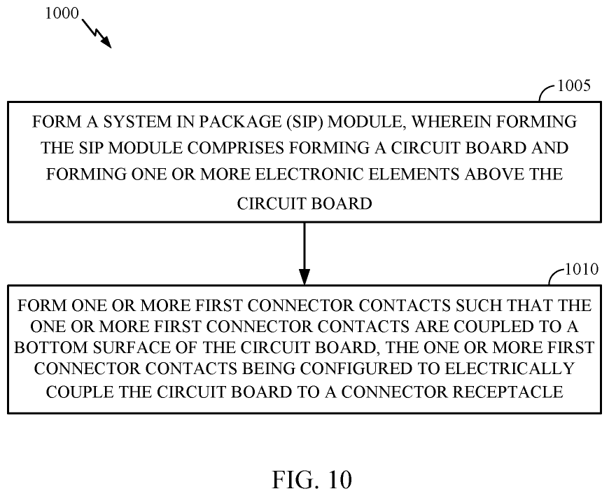

FIG. 10 is a flow diagram of example operations 1000 for fabricating an electronic device, or at least a portion of an electronic device (e.g., the portion of the electronic device 100, 400, 500, 600, or 700 described with respect to FIGS. 2, 3A, 3B, 4A, 4B, 5A, 5B, 6A, 6B, 7, 8A, and 8B), in accordance with certain aspects of the present disclosure. The operations 1000 may be performed, for example, by a fabrication facility.

The operations 1000 begin, at block 1005, with the fabrication facility forming a SIP module (e.g., the SIP module 102), where forming the SIP module includes forming a circuit board (e.g., the circuit board 208) and forming one or more electronic elements (e.g., the one or more components 902, 904, 906, 908, 910, 912, 914, 916, 918, 920) above the circuit board.

At block 1010, the facility forms one or more first connector contacts (e.g., the contacts 108) such that the one or more first connector contacts are coupled to a bottom surface of the circuit board. The one or more first connector contacts may be configured to electrically couple the circuit board to a connector receptacle (e.g., the connector 106).

In certain aspects, the facility may further form one or more second connector contacts (e.g., the side contact(s) 702) such that the one or more second connector contacts are coupled to a first lateral surface (e.g., the lateral surface 704 or 706) of the circuit board. The one or more second connector contacts may be configured to electrically couple the circuit board to the connector receptacle.

In certain aspects, the facility may further form the connector receptacle. The connector receptacle may be configured to be coupled to the circuit board. In this case, the connector receptacle may be formed such that the connector receptacle encircles an edge of the SIP module. The connector receptacle may include at least four walls surrounding a region for receiving the edge of the SIP module. Furthermore, in some cases, the facility forms a cable (e.g., the cable 300) configured to be connected to the connector receptacle.

In certain aspects, the facility may further form molding material (e.g., the molding 206) above the circuit board. The molding material may be formed such that the molding material encases the one or more electronic elements (e.g., the one or more components 902, 904, 906, 908, 910, 912, 914, 916, 918, 920).

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage, or mode of operation. The term “coupled” is used herein to refer to the direct or indirect coupling between two objects. For example, if object A physically touches object B and object B touches object C, then objects A and C may still be considered coupled to one another—even if objects A and C do not directly physically touch each other. For instance, a first object may be coupled to a second object even though the first object is never directly physically in contact with the second object. The terms “circuit” and “circuitry” are used broadly and intended to include both hardware implementations of electrical devices and conductors that, when connected and configured, enable the performance of the functions described in the present disclosure, without limitation as to the type of electronic circuits.

The apparatus and methods described in the detailed description are illustrated in the accompanying drawings by various blocks, modules, components, circuits, steps, processes, algorithms, etc. (collectively referred to as “elements”). These elements may be implemented using hardware, for example.

One or more of the components, steps, features, and/or functions illustrated herein may be rearranged and/or combined into a single component, step, feature, or function or embodied in several components, steps, or functions. Additional elements, components, steps, and/or functions may also be added without departing from features disclosed herein. The apparatus, devices, and/or components illustrated herein may be configured to perform one or more of the methods, features, or steps described herein.

It is to be understood that the specific order or hierarchy of steps in the methods disclosed is an illustration of exemplary processes. Based upon design preferences, it is understood that the specific order or hierarchy of steps in the methods may be rearranged. The accompanying method claims present elements of the various steps in a sample order, and are not meant to be limited to the specific order or hierarchy presented unless specifically recited therein.

The previous description is provided to enable any person skilled in the art to practice the various aspects described herein. Various modifications to these aspects will be readily apparent to those skilled in the art, and the generic principles defined herein may be applied to other aspects. Thus, the claims are not intended to be limited to the aspects shown herein, but are to be accorded the full scope consistent with the language of the claims, wherein reference to an element in the singular is not intended to mean “one and only one” unless specifically so stated, but rather “one or more.” Unless specifically stated otherwise, the term “some” refers to one or more. A phrase referring to “at least one of” a list of items refers to any combination of those items, including single members. As an example, “at least one of: a, b, or c” is intended to cover at least: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c). All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims. No claim element is to be construed under the provisions of 35 U.S.C. § 112(f) unless the element is expressly recited using the phrase “means for” or, in the case of a method claim, the element is recited using the phrase “step for.”

It is to be understood that the claims are not limited to the precise configuration and components illustrated above. Various modifications, changes and variations may be made in the arrangement, operation and details of the methods and apparatus described above without departing from the scope of the claims.

1. An electronic device comprising:
a system in package (SIP) module having a circuit board and one or more electronic elements disposed above the circuit board; and
one or more first connector contacts coupled to a bottom surface of the circuit board, the one or more first connector contacts being configured to electrically couple the circuit board to a connector receptacle.

2. The electronic device of claim 1, further comprising one or more second connector contacts coupled to a first lateral surface of the circuit board, the one or more second connector contacts being configured to electrically couple the circuit board to the connector receptacle.

3. The electronic device of claim 2, further comprising one or more third connector contacts coupled to a second lateral surface of the circuit board, the one or more third connector contacts being configured to electrically couple the circuit board to the connector receptacle.

4. The electronic device of claim 3, wherein the first lateral surface and the second lateral surface are on opposite sides of the circuit board.

5. The electronic device of claim 1, further comprising the connector receptacle coupled to the circuit board, wherein the connector receptacle is configured to encircle an edge of the SIP module.

6. The electronic device of claim 5, wherein the connector receptacle comprises at least four walls surrounding a region for receiving the edge of the SIP module.

7. The electronic device of claim 1, further comprising the connector receptacle coupled to the circuit board, the connector receptacle having a first supporting element and a second supporting element, a portion of the SIP module being disposed between the first supporting element and the second supporting element.

8. The electronic device of claim 7, wherein the connector receptacle comprises one or more second connector contacts on the first supporting element, the one or more first connector contacts being configured to electrically couple the circuit board to the one or more second connector contacts on the first supporting element.

9. The electronic device of claim 8, wherein the first supporting element is disposed adjacent to the bottom surface of the circuit board.

10. The electronic device of claim 9, further comprising one or more third connector contacts coupled to a top surface of the circuit board, the one or more third connector contacts being configured to electrically couple the circuit board to one or more fourth connector contacts on the second supporting element of the connector receptacle.

11. The electronic device of claim 7, wherein each of the first supporting element and the second supporting element comprises a connector wall disposed adjacent to a side of the SIP module.

12. The electronic device of claim 1, wherein the SIP module further comprises molding material disposed above the circuit board, the molding material encasing the one or more electronic elements.

13. The electronic device of claim 1, further comprising:
the connector receptacle coupled to the circuit board; and
a cable coupled to the connector receptacle.

14. The electronic device of claim 13, wherein:
the SIP module further comprises molding material disposed above the circuit board, the molding material encasing the one or more electronic elements;
the cable traverses along a surface of the molding material; and
the bottom surface of the circuit board and the surface of the molding material are on opposite sides of the SIP module.

15. The electronic device of claim 14, wherein the cable comprises:
conductive material configured to facilitate signaling between the SIP module and a circuit; and
a shielding sidewall disposed between the surface of the molding material and the conductive material.

16. The electronic device of claim 1, wherein the one or more first connector contacts comprise a plurality of first connector contacts arranged in one or more rows at an edge of the SIP module.

17. A connector receptacle comprising:
a first supporting element;
a second supporting element, the first supporting element and the second supporting element being configured to support a portion of a system in package (SIP) module to be disposed between the first supporting element and the second supporting element; and
one or more first connector contacts on the first supporting element, the one or more first connector contacts being configured to electrically couple a circuit to one or more second connector contacts coupled to a circuit board of the SIP module.

18. The connector receptacle of claim 17, wherein the connector receptacle is configured to encircle an edge of the SIP module.

19. The connector receptacle of claim 17, wherein each of the first supporting element and the second supporting element comprises a connector wall configured to be disposed adjacent to a side of the SIP module.

20. A method for fabricating an electronic device, comprising:
forming a system in package (SIP) module, wherein forming the SIP module comprises:
forming a circuit board, and
forming one or more electronic elements above the circuit board; and
forming one or more connector contacts such that the one or more connector contacts are coupled to a bottom surface of the circuit board, the one or more connector contacts being configured to electrically couple the circuit board to a connector receptacle.
